(19) United States
(12) Patent Application Publication
(10) Pub. No.: US 2008/0296745 A1
(43) Pub. Date: Dec. 4, 2008

(54) SEMICONDUCTOR DEVICE HAVING SEMICONDUCTOR CHIP AND ANTENNA

(75) Inventor: Kazuya KAWAMURA, Kawasaki-shi (JP)

Correspondence Address: YOUNG & THOMPSON, 209 Madison Street, Suite 500, ALEXANDRIA, VA, 22314, US

(73) Assignee: NEC ELECTRONICS CORPORATION, Kanagawa (JP)

(21) Appl. No.: 12/131,216

(22) Filed: Jun. 2, 2008

(30) Foreign Application Priority Data
Jun. 1, 2007 (JP) 2007-146787

(51) Int. Cl. H01L 23/495; H01L 23/34

(52) U.S. Cl. 257/666; 257/728; 257/E23.031

(57) ABSTRACT

A semiconductor device comprises a lead frame, an antenna formed at a predetermined position on the lead frame, and a semiconductor chip. The semiconductor chip is mounted on an island of the lead frame through a spacer.

### BACKGROUND OF THE INVENTION

1. Field of the Invention

The present invention relates to a semiconductor device having a semiconductor chip and an antenna.

This application is based upon and claims the benefit of priority from Japanese patent application No. 2007-146787, filed on Jun. 1, 2007, the disclosure of which is incorporated herein in its entirely by reference.

2. Description of Related Art

Japanese Laid-Open Patent Application JP-P2005-346412 discloses a semiconductor device provided with a semiconductor chip such as a CPU and an RFID (Radio Frequency IDentification) chip that performs radio communication with an external device. The RFID chip is a noncontact type, which receives power and data from the external device and transmits data to the external device through an antenna.

The above-mentioned semiconductor chip is mounted on an island of a lead frame. The lead frame has a suspension pin that is member for supporting the island, and a slit is formed at a part of the suspension pin. The slit serves as a “slit antenna” that the RFID chip uses in the radio communication. In other words, the slit antenna is formed on the lead frame and the RFID chip is electrically connected to the slit antenna.

According to the above-described technique, a part of the lead frame is used as the antenna for the RFID chip. As a result, there is no need to prepare an antenna-specific region, which prevents increase in a package size.

The inventor of the present application has recognized the following point. When the semiconductor device is provided with the RFID chip in addition to the semiconductor chip such as a CPU as described above, the external device may not be able to establish communication with the RFID chip due to the following problem. The semiconductor chip mounted on the island of the lead frame is electrically connected to lead electrodes of the lead frame through bonding wires. The bonding wires disturb electromagnetic field and thus the external device becomes unable to communicate with the RFID chip due to transmission loss.

### SUMMARY

According to an experiment conducted by the inventor of the present application, it was found that an electromagnetic wave receivable distance from the RFID chip becomes longer as the semiconductor chip connected to the bonding wires is placed more away from the island. That is to say, it was found that the transmission loss of electromagnetic wave from the RFID chip is reduced as a distance between the semiconductor chip connected to the bonding wire and the lead frame becomes larger.

Therefore, in one embodiment of the present invention, a semiconductor device has the following configuration. That is, the semiconductor device is provided with a lead frame, an antenna formed at a predetermined position on the lead frame, and a semiconductor chip mounted on an island of the lead frame through a spacer. The spacer is a different member from adhesive.

As described above, the spacer is provided between the lead frame having the antenna and the semiconductor chip. Since the spacer is provided, a distance between the semiconductor chip and the lead frame becomes larger. Due to the above configuration, the transmission loss of electromagnetic wave from the antenna is reduced. As a result, excellent radio communication can be established.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is a plan view showing a configuration example of a semiconductor device according to an embodiment of the present invention;

FIG. 2A is a cross-sectional view showing a structure along a line A-A′ in FIG. 1;

FIG. 2B is a cross-sectional view showing a structure along a line B-B′ in FIG. 1;

FIG. 3 is a block diagram showing a configuration example of a second semiconductor chip according to the present embodiment;

FIG. 4 is a plan view showing the second semiconductor chip and a slit antenna according to the present embodiment;

FIG. 5 is a schematic diagram for explaining an experimental condition;

FIG. 6 is a table showing an experimental result;

FIG. 7 is a cross-sectional view showing a modified example of the present embodiment; and

FIG. 8 is a cross-sectional view showing another modified example of the present embodiment.

### DETAILED DESCRIPTION OF PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposed.

### 1. Configuration

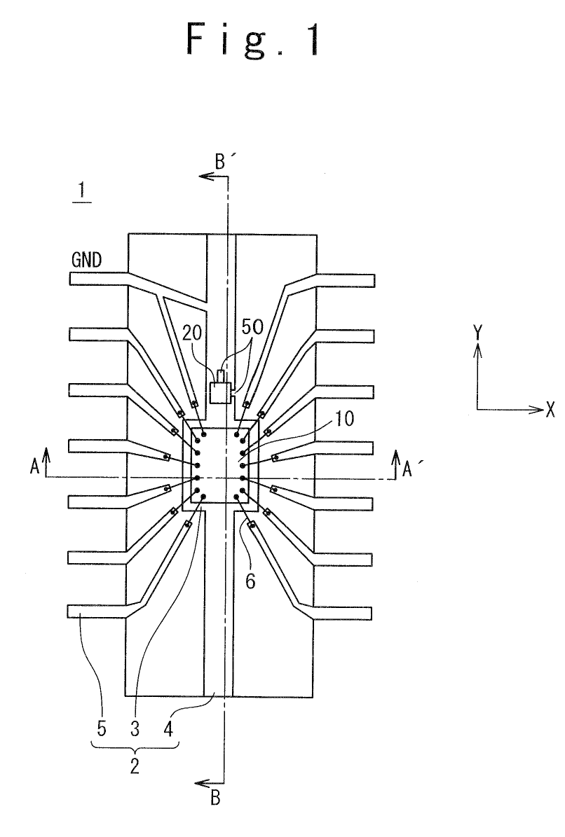

FIG. 1 is a plan view schematically showing a configuration example of a semiconductor device 1 according to an embodiment of the present invention. The semiconductor device 1 is provided with a lead frame 2, a first semiconductor chip 10, a second semiconductor chip 20 and an antenna 50. The lead frame 2 includes an island 3, a suspension pin 4 and lead electrodes 5. The suspension pin 4 is a member connected to the island 3 and for supporting the island 3. In FIG. 1, a longitudinal direction of the suspension pin 4 is a Y-direction, and a direction perpendicular to the Y-direction is a X-direction.

The first semiconductor chip 10 is an IC chip such as a microprocessor and memory. The first semiconductor chip 10 is so provided as to overlap with the island 3 of the lead frame 2. Electrode pads of the first semiconductor chip 10 are electrically connected to the lead electrodes 5 through bonding wires 6, respectively. Power is supplied to the first semiconductor chip 10 from the lead electrode 5 through the bonding wire 6.

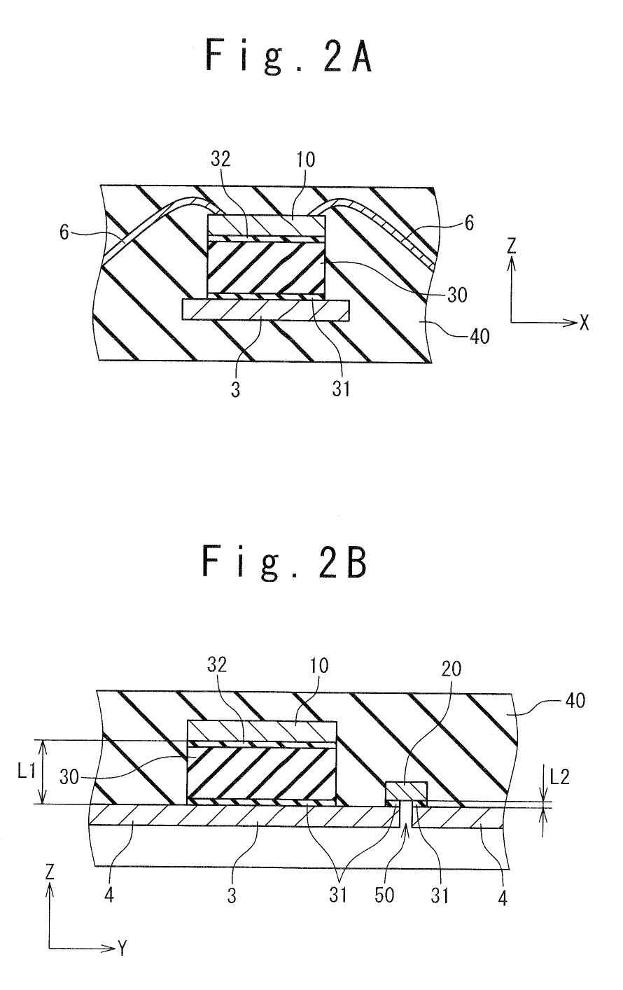

FIG. 2A is a cross-sectional view showing a structure along a line A-A′ in FIG. 1 and illustrates a cross-sectional structure including the first semiconductor chip 10. A plane shown in FIG. 2A is a XZ plane perpendicular to the XY plane shown in FIG. 1. As shown in FIG. 2A, the first semiconductor chip 10 is mounted on the island 3 (first position) through a “spacer 30”. In other words, the spacer 30 is provided between the first semiconductor chip 10 and the island 3, and thus a distance between the first semiconductor chip 10 and the island 3 becomes larger as compared with a typical one.

The spacer 30 is bonded to the island 3 with adhesive 31 and bonded to the first semiconductor chip 10 with adhesive 32. That is to say, the spacer 30 is a different member from adhesive that is usually used. The spacer 30 is made of insulating material. For example, material of the spacer 30 includes any of glass, ceramic and silicon.

Moreover, the first semiconductor chip 10 is connected to the bonding wire 6, as shown in FIG. 2A. The above-described structure is encapsulated by molding compound 40.

Referring FIG. 1 again, the second semiconductor chip 20 is mounted on the suspension pin 4 of the lead frame 2. Furthermore, the antenna 50 is formed at a predetermined position on the suspension pin 4. The second semiconductor chip 20 is an RFID (Radio Frequency IDentification) chip that is electrically connected to the antenna 50 and performs radio communication with an external device (the outside of the semiconductor device 1) by using the antenna 50. For example, the second semiconductor chip 20 is a noncontact RFID chip, which receives power and data from the external device and transmits data to the external device through the antenna 50.

FIG. 2B is a cross-sectional view showing a structure along a line B-B′ in FIG. 1 and illustrates a cross-sectional structure including the first semiconductor chip 10 and the second semiconductor chip 20. A plane shown in FIG. 2B is a YZ plane perpendicular to the XY plane shown in FIG. 1. As shown in FIG. 2B, the second semiconductor chip 20 is placed on the antenna 50 that is formed at a predetermined position (second position) of the suspension pin 4. For example, the second semiconductor chip 20 is bonded to the suspension pin 4 around the antenna 50 with the adhesive 31. Alternatively, two I/O terminals 26 (described later) of the second semiconductor chip 20 may be soldered on the suspension pin 4 around the antenna 50.

As shown in FIG. 2B, a distance between the island 3 of the lead frame 2 and the first semiconductor chip 10 is L1. On the other hand, a distance between the suspension pin 4 of the lead frame 2 on which the antenna 50 is formed and the second semiconductor chip 20 is L2. According to the present embodiment, a relation “L1>L2” is satisfied because the spacer 30 is provided as described above. That is to say, the first semiconductor chip 10 is placed more away from the lead frame 2 than the second semiconductor chip 20 is.

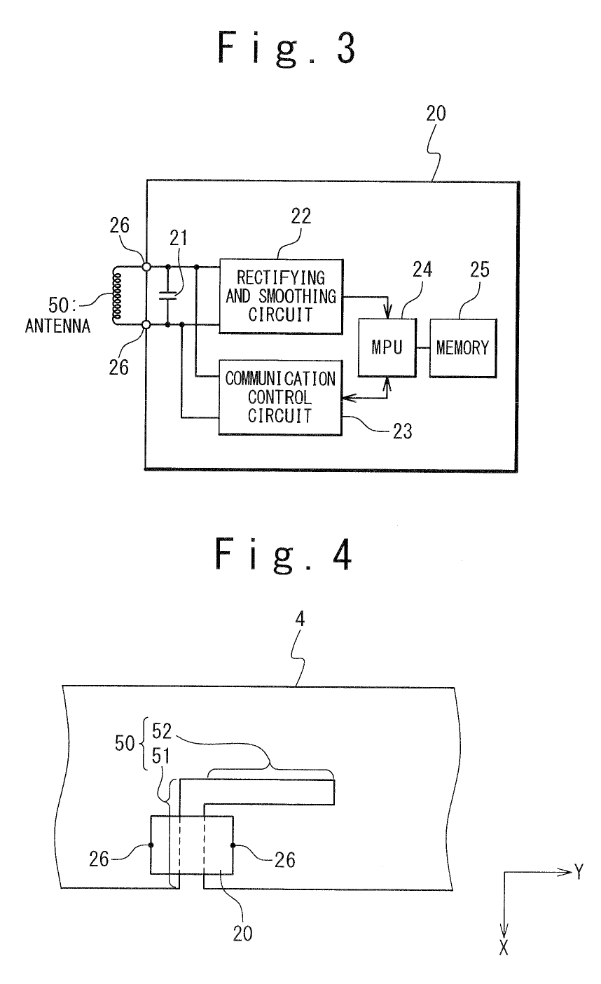

FIG. 3 is a block diagram showing a configuration example of the second semiconductor chip 20. The second semiconductor chip 20 is provided with a resonant capacitor 21, a rectifying and smoothing circuit 22, a communication control circuit 23, an MPU (Micro Processing Unit) 24, a memory 25 and two I/O terminals 26 connected to the antenna 50. The resonant capacitor 21, the rectifying and smoothing circuit 22 and the communication control circuit 23 are connected to the I/O terminals 26.

The rectifying and smoothing circuit 22 receives AC power through the antenna 50 and the resonant capacitor 21 and coverts the AC power into DC power. The MPU 24 operates based on the DC power. The communication control circuit 23 demodulates data received through the antenna 50 and outputs the demodulated data to the MPU 24. The memory 25 is, for example, an EEPROM (Electrically Erasable Programmable ROM) in which ID information and operating programs of the MPU 24 are stored. The MPU 24 processes the demodulated data, reads the ID information from the memory 25, and so on. A transmission data output from the MPU 24 is modulated by the communication control circuit 23. Then, the modulated data is transmitted to the external device through the antenna 50.

FIG. 4 is a plan view showing the second semiconductor chip 20 and the antenna 50 in the present embodiment. The antenna 50 is a “slit antenna” that is formed by cutting out a part of the suspension pin 4. More specifically, the slit antenna 50 consists of a first slit 51 along the X-direction and a second slit 52 along the Y-direction. The second slit 52 is linked to the first slit 51 and extends in a direction away from the first semiconductor chip 10. A region of the suspension pin 4 surrounded by the first slit 51 and second slit 52 defines inductance component of the slit antenna 50. It is possible to transmit and receive a signal of a desired frequency by adjusting the length of the second slit 52. That is to say, tuning of the slit antenna 50 is possible by adjusting the length of the second slit 52.

The second semiconductor chip 20 performs radio communication with the external device by using the slit antenna 50. In the example shown in FIG. 4, the second semiconductor chip 20 is so places as to straddle the first slit 51. The two I/O terminals 26 of the second semiconductor chip 20 are respectively connected to sections on both sides of the first slit 51. Consequently, the second semiconductor chip 20 is electrically connected to the slit antenna 50. It should be noted that the suspension pin 4 is connected to a lead electrode 5 that is connected to the ground GND (see FIG. 1).

### 2. Experiment

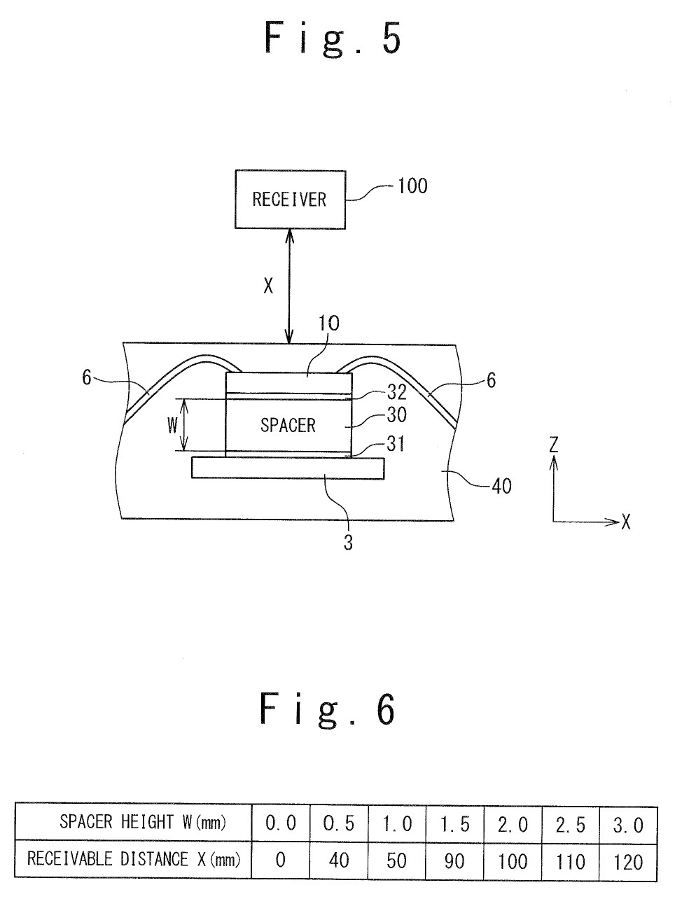

The inventor of the present application carried out an experiment to examine dependence of RFID communication on a thickness of the spacer 30. FIG. 5 is a schematic diagram for explaining the experimental condition.

The material of the spacer 30 is glass, and the thickness (height) of the spacer 30 is “W”. The molding compound 40 is MPT (made by Matsushita Electric Works, Ltd.). Material of the lead frame 2 is copper. A shape of the island 3 is a rectangle of 8.0×6.0 mm. A width of the suspension pin 4 is 2.0 mm. A slit width of the slit antenna 50 is 0.2 mm. A length of the first slit 51 is 1.5 mm and a length of the second slit 52 is 7.0 mm. A frequency of the RFID radio wave is 2.45 GHz. Communication with respect to the second semiconductor chip 20 was performed under the above-mentioned experimental condition by using a receiver 100. A maximum receivable distance “X” by the receiver 100 was measured for various thicknesses W.

FIG. 6 shows the result of the experiment. The thickness (height) W of the spacer 30 is varied in a rage from 0 to 3.0 mm. As shown in FIG. 6, the receivable distance X becomes longer as the thickness W of the spacer 30 becomes larger. That is to say, the electromagnetic wave receivable distance X from the second semiconductor chip 20 becomes longer as the first semiconductor chip 10 is placed more away from the lead frame 2. The reason is considered to be as follows.

As the first semiconductor chip 10 is more away from the lead frame 2, the bonding wire 6 also is more away from the lead frame 2. This means that the bonding wire 6 is more away from the slit antenna 50. Therefore, influence of the bonding wire 6 on the RFID radio wave is reduced and disturbance of electromagnetic field by the bonding wire 6 is suppressed. As a result, the transmission loss of the RFID radio wave is reduced and thus the receivable distance X is increased.

The receivable distance X being short is not preferable from a viewpoint of practical use. In a case of a handy reader, for example, the receivable distance X is preferably equal to or more than 50 mm. It can be seen from FIG. 6 that the thickness W need to be not less than 1.0 mm in order to achieve the receivable distance X of not less than 50 mm. That is to say, it is preferable that the thickness W of the spacer 30 is not less than 1.0 mm. It should be noted that the thickness W of the spacer 30 is set to the extent that the first semiconductor chip 10 does not protrude out of the package.

### 3. Effects

According to the present embodiment, as described above, the spacer 30 is provided between the lead frame 2 having the antenna 50 and the first semiconductor chip 10. Since the spacer 30 is provided, the distance between the first semiconductor chip 10 and the lead frame 2 becomes larger. Due to such the configuration, the transmission loss of electromagnetic wave from the antenna 50 is reduced. As a result, excellent RFID communication can be established.

Moreover, the spacer 30 is made of insulating material according to the present embodiment, which brings about the following effect. Let us assume a case where the first semiconductor chip 10 is bonded to the island 3 with conductive adhesive such as silver paste, as in a typical semiconductor device. In this case, the suspension pin 4 is electrically connected to a lead electrode 5 when the first semiconductor chip 10 is connected to the lead electrode 5 through the bonding. That is, the suspension pin 4 on which the antenna 50 is formed is electrically connected to the power supply, which changes characteristics of the antenna 50. In the present embodiment, however, the spacer 30 made of the insulating material intervenes between the first semiconductor chip 10 and the island 3. Therefore, the suspension pin 4 is electrically separated from the power supply, which prevents the change in the characteristics of the antenna 50.

### 4. Modified Example

The structure for separating the first semiconductor chip 10 from the island 3 is not limited to that shown in FIGS. 2A and 2B.

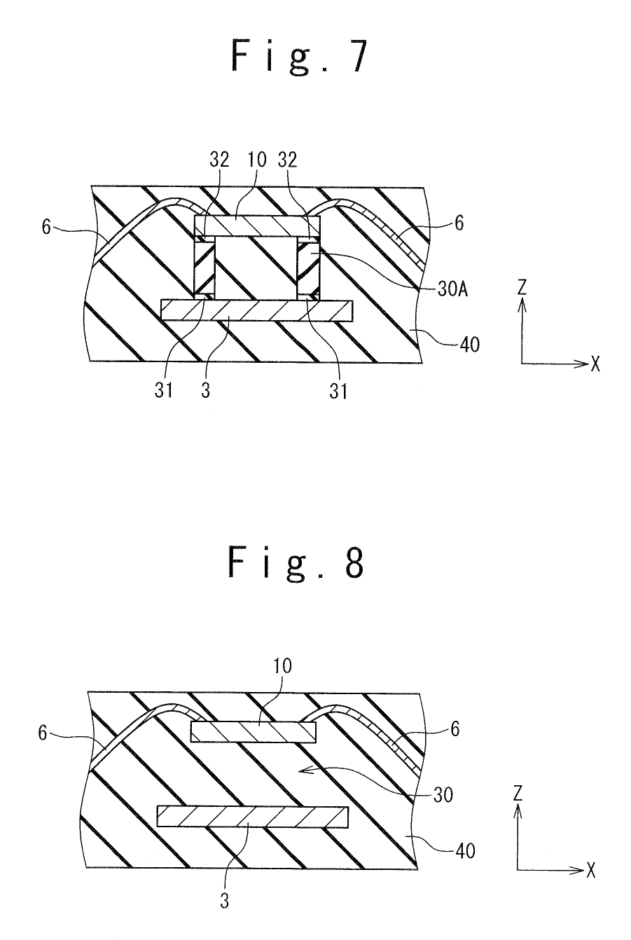

For example, as shown in FIG. 7, a columnar spacer 30A having a columnar structure can be used. In this case, the first semiconductor chip 10 is placed on a plurality of columnar spacers 30A. Each columnar spacer 30A is bonded to the island 3 and the first semiconductor chip 10 through the adhesive 31 and 32, respectively. It is preferable that each columnar spacer 30A is made of insulating material. Note that the molding compound 40 intrudes into a space between the first semiconductor chip 10 and the island 3. The above-mentioned effects can be obtained also by the structure shown in FIG. 7.

As another example, the molding compound 40 can serve as the spacer 30, as shown in FIG. 8. That is to say, the spacer 30 is made of molding compound 40. Such a structure can be achieved, for example, by dividing the molding compound injection process into plural stages. First, the molding compound 40 is injected only onto the island 3. Next, the first semiconductor chip 10 is mounted on the molding compound 40, and the wire bonding is performed. After that, the molding compound 40 is injected again such that the whole is encapsulated. The above-mentioned effects can be obtained also by the structure shown in FIG. 8.

As described above, it is possible to achieve the structure that satisfies the above-mentioned relation “L1>L2”, by using the spacer 30, the columnar spacer 30A or the molding compound 40. Consequently, the above-described effects can be obtained.

It is apparent that the present invention is not limited to the above embodiments and may be modified and changed without departing from the scope and spirit of the invention.

What is claimed is:

1. A semiconductor device comprising:
a lead frame;
an antenna formed at a predetermined position on said lead frame; and
a semiconductor chip mounted on an island of said lead frame through a spacer.

2. The semiconductor device according to claim 1,
wherein said spacer is made of insulating material.

3. The semiconductor device according to claim 2,
wherein material of said spacer includes any of glass, ceramic and silicon.

4. The semiconductor device according to claim 3,
wherein material of said spacer is glass.

5. The semiconductor device according to claim 1,
wherein said spacer is bonded to said island and said semiconductor chip with adhesive.

6. The semiconductor device according to claim 2,
wherein material of said spacer is molding compound.

7. The semiconductor device according to claim 1,
wherein a thickness of said spacer is not less than 1 mm.

8. The semiconductor device according to claim 1,
wherein said semiconductor chip is electrically connected to a lead electrode of said lead frame through a bonding wire.

9. The semiconductor device according to claim 1,
wherein said semiconductor chip is a first semiconductor chip, said semiconductor device further comprising a second semiconductor chip electrically connected to said antenna,
wherein said second semiconductor chip communicates with an external device by using said antenna.

10. The semiconductor device according to claim 9,
wherein said antenna is a slit antenna formed on said lead frame, and said second semiconductor chip is so placed as to straddle a slit of said slit antenna.

11. A semiconductor device comprising:
a lead frame;
a first semiconductor chip placed on a first position of said lead frame; and
a second semiconductor chip placed on an antenna that is formed at a second position of said lead frame,
wherein a distance between said first semiconductor chip and said lead frame is larger than a distance between said second semiconductor chip and said lead frame.
